(19) United States
(12) Patent Application Publication
(10) Pub. No.: US 2025/0003694 A1
(43) Pub. Date: Jan. 2, 2025

(54) WICK STRUCTURE FOR OPTIMIZED THERMAL PERFORMANCE AND METHOD OF MAKING THE SAME

(71) Applicant: NVIDIA CORPORATION, Santa Clara, CA (US)

(72) Inventors: Ron CHAO, San Diego, CA (US); Elad Mentovich, Tel Aviv (IL); Harrison Sangwha Kim, Morgan Hill, CA (US); Mark North, Lancaster, PA (US); Xinwei Lu, Shenzhen (CN); Tahir Cader, Spokane Valley, WA (US); Fei Zhang, Shenzhen (CN); Yunseok Kim, Pleasanton, CA (US); David Haley, Beaverton, OR (US); Yuezhan Steven Zhu, San Jose, CA (US); Lei Huang, Shenzhen (CN)

(21) Appl. No.: 18/223,154

(22) Filed: Jul. 18, 2023

Related U.S. Application Data
(63) Continuation of application No. PCT/CN2023/105075, filed on Jun. 30, 2023.

(51) Int. Cl. F28D 15/04; F28D 15/02

(52) U.S. Cl. CPC F28D 15/046; F28D 15/0266; F28D 2021/0029

(57) ABSTRACT

A heat transfer apparatus including a housing and a wick structure is provided that is configured to dissipate heat from a heat source. The housing defines a chamber that holds working fluid. The wick structure includes a body and pores defined by the body. The heat transfer apparatus defines an evaporator section configured to evaporate the working fluid using heat from a heat source and a condenser section configured to dissipate heat carried by the evaporated working fluid through condensation of the evaporated working fluid. The wick structure has a repeatable, configurable, and controlled geometry optimized to move the working fluid from the condenser section to the evaporator section via capillary action. The body of the wick structure may have a gyroidal geometry. Associated methods are also provided.

### CROSS-REFERENCE TO RELATED APPLICATIONS

This application is a continuation of International Application No. PCT/CN2023/105075, filed Jun. 30, 2023, the entire contents of which are incorporated herein by reference.

### TECHNOLOGICAL FIELD

Example embodiments of the present disclosure relate generally to heat transfer apparatuses, such as cooling fixtures including vapor chambers and heat pipes, and, more particularly, to heat transfer apparatuses that are optimized for use in high-performance networking and computing systems as well as other electronic devices and components.

### BACKGROUND

High-performance computing systems, such as those used in datacenters and other networking environments (e.g., datacom, telecom, and/or other similar data/communication transmission networks), may leverage numerous electronic components (e.g., central processing units (CPUs), graphics processing unit (GPUs), etc.) to perform the operations associated with these environments. During operation, the heat generated by these components may impact the overall operation of the computing systems, particularly as the operational capability of these components increases. Apparatuses for heat transfer, such as vapor chambers and heat pipes, are often used for dissipating heat from such heat sources.

Applicant has identified a number of deficiencies and problems associated with conventional heat transfer apparatuses. Through applied effort, ingenuity, and innovation, many of these identified problems have been solved or mitigated by developing solutions that are included in embodiments of the present disclosure, many examples of which are described in detail herein.

### BRIEF SUMMARY

Apparatuses and methods are provided for improved thermal management in networking computing devices. In particular, heat transfer apparatuses, such as cooling fixtures (e.g., vapor chambers and heat pipes), are described herein that are optimized through the use of an application-oriented, design-based wick structure to maximize the thermal performance of the apparatus in a particular operating scenario according to the laws of physics. With reference to an example heat transfer apparatus configured to dissipate heat from a heat source, the apparatus may include a housing defining a chamber configured to hold working fluid, and a wick structure comprising a body and pores defined by the body. The wick structure may be disposed on an interior surface of the housing. The heat transfer apparatus may define an evaporator section configured to evaporate the working fluid using heat from a heat source and a condenser section configured to dissipate heat carried by the evaporated working fluid through condensation of the evaporated working fluid. The wick structure may comprise a repeatable, configurable, and controlled geometry that is configured to move the working fluid from the condenser section to the evaporator section via capillary action.

In some embodiments, the body of the wick structure may have a gyroidal geometry.

The geometry of the wick structure may be configured to promote heat transfer in at least one predetermined area of the heat transfer apparatus corresponding to a hot spot of the heat source.

In some cases, the heat transfer apparatus may be a cooling fixture comprising a vapor chamber or a heat pipe. The heat source may, in some cases, be an integrated microchip.

In some embodiments, the wick structure may be anisotropic.

In some embodiments, dimensional parameters of the wick structure may be configured to optimize at least one of (i) the capillary action of the pores, (ii) thermal conduction through the wick structure, or (iii) a structural integrity of the heat transfer apparatus. The pores defined by the body of the wick structure may have a variable pore size configured to optimize at least one of (i) the capillary action of the pores, (ii) thermal conduction through the wick structure, or (iii) a structural integrity of the heat transfer apparatus. The geometry of the wick structure may be configured to define at least one predetermined path between the evaporator section and the condenser section of the heat transfer apparatus.

In some embodiments, the heat transfer apparatus may further comprise at least one post disposed within the chamber and affixed to the housing, wherein the at least one post is configured to increase a structural integrity of the heat transfer apparatus. The at least one post may, in some cases, be hollow. Additionally or alternatively, the at least one post may comprise a secondary wick structure configured to move the working fluid from the condenser section to the evaporator section via capillary action.

In some cases, at least one of the housing or the wick structure may be formed using an additive manufacturing process.

A method of manufacturing a heat transfer apparatus is also provided according to embodiments described herein, wherein the method is configured to dissipate heat from a heat source. The method may comprise providing a housing that defines a chamber configured to hold working fluid and forming a wick structure comprising a body and pores defined by the body, where the body of the wick structure has a repeatable, configurable, and controlled geometry. The method may further comprises applying the wick structure to an interior surface of the housing. In some cases, the heat transfer apparatus may define an evaporator section configured to evaporate the working fluid using heat from a heat source and a condenser section configured to dissipate heat carried by the evaporated working fluid through condensation of the evaporated working fluid. The wick structure may be configured to move the working fluid from the condenser section to the evaporator section via capillary action.

In some embodiments, forming the wick structure may comprise using an additive manufacturing process. Additionally or alternatively, the method may further comprise determining an optimal design of the geometry of the wick structure, wherein the optimal design optimizes at least one of (i) the capillary action of the pores, (ii) thermal conduction through the wick structure, or (iii) a structural integrity of the heat transfer apparatus.

In some cases, the optimal design may comprise at least one of a variable diameter d of interconnecting extensions of the body, a variable absolute thickness t of the wick structure, or a variable size of the pores of the wick structure.

The geometry of the wick structure may be configured to promote heat transfer in at least one predetermined area of the heat transfer apparatus corresponding to a hot spot of the heat source. In some cases, the geometry of the wick structure may be gyroidal.

In some embodiments, the method may comprise disposing at least one post within the chamber, wherein the at least one post is affixed to the housing, and wherein the at least one post is configured to increase a structural integrity of the heat transfer apparatus.

In still other embodiments, a heat transfer apparatus is provided that is configured to dissipate heat from a heat source. The apparatus may comprise a housing defining a chamber configured to hold working fluid and a wick structure comprising a body and pores defined by the body. The wick structure may be disposed on an interior surface of the housing. The heat transfer apparatus may define an evaporator section configured to evaporate the working fluid using heat from a heat source and a condenser section configured to dissipate heat carried by the evaporated working fluid through condensation of the evaporated working fluid. The wick structure may be configured to move the working fluid from the condenser section to the evaporator section via capillary action. The body of the wick structure may have a repeatable, configurable, and controlled geometry configured to maximize a thermal performance of the heat transfer apparatus.

In some embodiments, the geometry of the wick structure may be gyroidal.

In some embodiments, the wick structure may be formed using an additive manufacturing process.

In some cases, the wick structure may comprise at least one of a variable diameter d of interconnecting extensions of the body, a variable absolute thickness t of the wick structure, or a variable size of the pores of the wick structure.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures. These figures are provided to facilitate the understanding of the embodiments described herein and may not be depicted to scale.

FIG. 1 illustrates a side view of an example heat transfer apparatus for dissipating heat from a heat source in accordance with some embodiments described herein;

FIG. 2 illustrates a perspective view of a portion of an example wick structure of the heat transfer apparatus of FIG. 1 in accordance with some embodiments described herein;

FIG. 3 illustrates a side view of an example heat transfer apparatus for dissipating heat from a heat source, where the heat transfer apparatus includes additional mechanical structures and heat transfer features in accordance with some embodiments described herein; and

FIG. 4 is a flowchart illustrating a method of manufacturing a heat transfer apparatus configured to dissipate heat from a heat source in accordance with some embodiments described herein.

### DETAILED DESCRIPTION

Embodiments of the present disclosure now will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear,” “top,” “above,” “below,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As described above, apparatuses for heat transfer, such as cooling fixtures including vapor chambers and heat pipes, are often used for dissipating heat from heat sources. In the context of networking computing devices and environments, for example, heat transfer apparatuses may be used to dissipate heat from integrated microchips, such as graphics processing units (GPUs) and central processing units (CPUs), as well as other electronic components or objects capable of generating heat. Such apparatuses typically include a wick structure for absorbing working fluid and distributing the working fluid from cooler to hotter areas of the heat transfer apparatus to form a closed loop of evaporation, condensation, and backflow within the chamber, thereby creating an isothermal heat spreader. In particular, heat from a heat source passes into an evaporator section of the heat transfer apparatus and vaporizes working fluid within the wick structure. The evaporated working fluid, now in the form of a vapor, moves to a condenser section of the heat transfer apparatus, where it condenses on condenser surfaces of the apparatus, releasing heat. The heat can then be dissipated from the heat transfer apparatus, such as by forced convection and/or through the use of other heat transfer means (e.g., fins). The condensed working fluid in the condenser section is then moved back to the evaporator section via capillary action of the wick structure, where the cycle begins again.

Conventional wick structures may include porous surfaces on an interior of the heat transfer apparatus (e.g., an interior surface of the vapor chamber or heat pipe), copper powder sintering, metal mesh, or combinations of these. Such conventional wick structures, however, have several deficiencies, as the performance of these conventional structures cannot be accurately modeled or designed to produce predetermined results due to the random (e.g., irregular and/or non-repeatable) wick structure that is formed and the resulting random and uncontrollable capillary action. Moreover, the performance of some such conventional wick structures cannot be reliably predicted due to variations in the powder size, sintering, and other manufacturing parameters, including the random formation of the wick structures themselves by such processes.

Embodiments of the invention described herein relate to a new wick structure that incorporates a highly repeatable, configurable, and controlled geometry that is specifically designed using the laws of physics to maximize liquid flow, minimize pressure drop, maximize evaporation and condensation, and/or maximize structural support in identified areas for optimizing the performance of the wick structure for the given application. Said differently, the geometry of the wick structure may be determined (e.g., using computer modelling techniques as described herein) to achieve particular localized performance and/or overall performance, and the wick structure can be manufactured according to the determined geometry across multiple different heat transfer devices for effecting the same optimized performance in a predetermined, consistent, and predictable manner.

In some cases, for example, a gyroidal geometry may be used for the wick structure, which can be optimized to perform in a predetermined, consistent, and predictable manner. As described in greater detail below, the geometry according to embodiments of the invention can be modeled to determine the porosity and pore size needed to move a certain volume of working fluid at a predetermined rate while still providing optimized thermal conductivity and maintaining an operable structural integrity of the heat transfer apparatus (e.g., the vapor chamber or heat pipe). Moreover, the pore size and “bone” thickness of the wick structure can be varied across the whole of the wick structure to promote heat transfer in certain areas of the apparatus, such as to more efficiently dissipate heat from hot spots (locations of the heat source that generate more heat and therefore need additional cooling). The wick structure according to embodiments of the invention also allows for anisotropic performance, thereby further enabling optimal capillary action, minimizing inefficient backflow, and allowing directional distribution of working fluid within the heat transfer apparatus to provide heat transfer that is customized to the particular application. In some embodiments, posts may be included within the heat transfer apparatus to increase the structural integrity of the apparatus. These posts may be hollow to reduce weight and/or provide a conduit for evaporated working fluid, or the posts may themselves include a wick structure (which may be designed to have a geometry in accordance with embodiments of the present invention) to provide additional pathways for moving working fluid to the evaporator section of the heat transfer apparatus, as described in greater detail below.

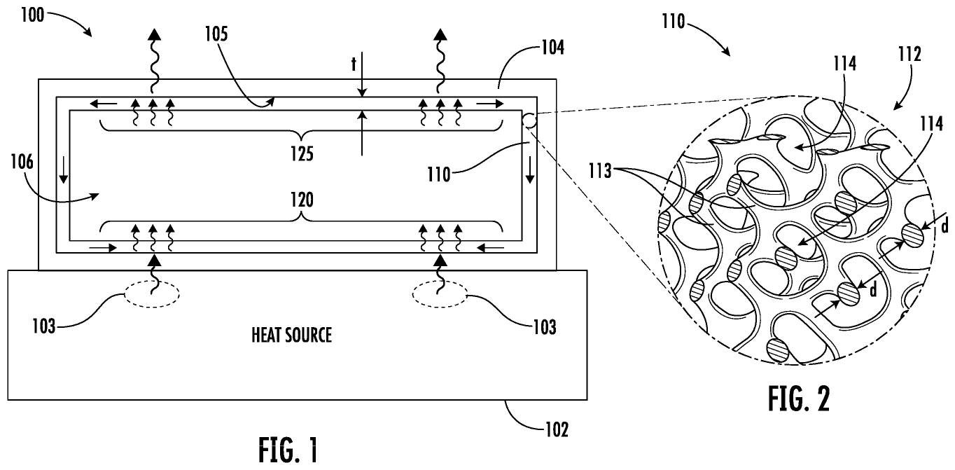

With reference to FIG. 1, a heat transfer apparatus 100 is shown that is configured to dissipate heat from a heat source 102. As described in greater detail below, the heat transfer apparatus 100 may be, in some cases, a cooling fixture. For example, the cooling fixture may be a vapor chamber or a heat pipe. The heat source 102 may be any device, component, or object that generates heat or has a temperature that is higher than the temperature of its surroundings. In the context of a datacenter, for example, the heat source 102 may be an integrated microchip. The heat source 102 may, for example, be a GPU, a CPU, or another electronic component that, when operating, produces heat.

Because heat may damage or negatively affect the function or structure of the heat source 102 or surrounding devices or components, a heat transfer apparatus such as the heat transfer apparatus 100 may be installed to dissipate heat from the heat source. The heat transfer apparatus 100 may, for example, be disposed in contact with or near the heat source 102, so as to draw heat from the heat source through conduction, convection, radiation, and/or other heat transfer mechanisms. The heat transfer apparatus 100 may be further configured to discharge the heat drawn from the heat source 102 in a location that is distanced from the heat source so as to remove the heat from the heat source and its surroundings.

As such, embodiments of the heat transfer apparatus 100 may comprise a housing 104 and a wick structure 110 disposed on an interior surface 105 of the housing 104. The housing 104 may define a chamber 106 configured to hold working fluid (evaporated and/or liquid forms). In this regard, working fluid may be any liquid that is able to act as a heat sink, can be evaporated in the presence of heat, and can recondense to liquid form, thereby releasing absorbed heat. Working fluid may include, for example, water, ammonia, alcohol (e.g., ethanol), or combinations thereof.

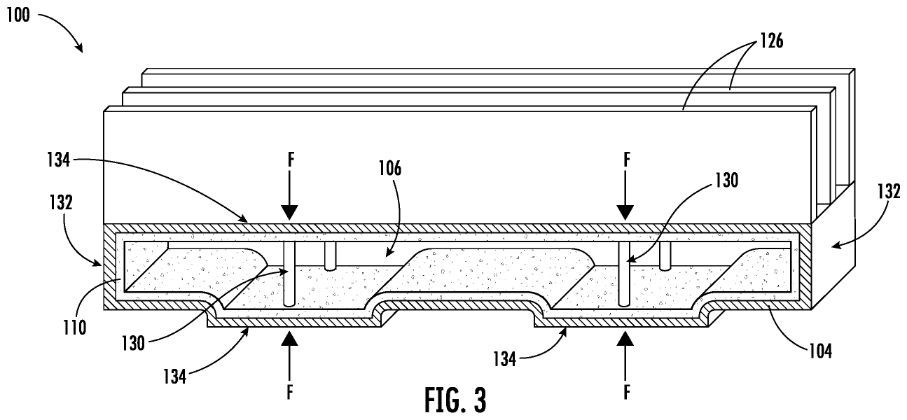

The heat transfer apparatus 100 may define an evaporator section 120 and a condenser section 125. The evaporator section 120 may be configured to evaporate the working fluid using heat from the heat source, and the condenser section 125 may be configured to dissipate heat carried by the evaporated working fluid through condensation of the evaporated working fluid. In the example of FIG. 1, heat, which is depicted using wavy line arrows, enters the heat transfer apparatus 100 via an evaporator section 120 located at the bottom of the housing 104. Evaporated working fluid rises to the condenser section 125, which is located at the top of the housing 104 (e.g., the upper portion of the chamber 106) in the depicted example, and is released and dissipated via the top of the housing. In other embodiments not shown, however, heat may enter an evaporator section located at one end of the heat transfer apparatus, such as a right end or a left end, and may be dissipated via a condenser section located at the other end (e.g., the left end or the right end, respectively). In some embodiments, as shown in FIG. 3, additional heat dissipation elements such as fins 126 may be provided in thermal communication with the condenser section 125 (shown in FIG. 1) of the heat transfer apparatus 100 to facilitate the dissipation of the heat released through condensation of the evaporated working fluid in the condenser section. Such fins 126 may, for example, be attached to the exterior of the housing 104 of the heat transfer apparatus 100 proximate the condenser section 125. In this way, heat released from the evaporated working fluid as it condenses in the condenser section 125 may be conducted or otherwise transmitted through the housing 104 to the fins 126, and the heat can in turn be dissipated (e.g., through radiation or other heat transfer mechanisms) to the ambient environment via the fins.

The wick structure 110, shown in greater detail in FIG. 2, may comprise a body 112 and pores 114 defined by the body. The pores 114, which may be openings or voids in the material of the wick structure 110, may be configured to move the working fluid from the condenser section 125 to the evaporator section 120 via capillary action.

In some embodiments, the wick structure 110 comprises a repeatable, configurable, and controlled geometry. For example, the number, dimensions, and arrangement of the pores 114 defined by the body 112 and/or the three-dimensional surface of the body 112 may be described by one or more equations or a set of instructions, such that a second wick structure of a second heat transfer apparatus 100 may be manufactured having an identical or substantially identical (e.g., within acceptable engineering tolerances) design. Moreover, such geometry (e.g., the number, dimensions, and arrangement of the pores 114 defined by the body 112 and/or the three-dimensional surface of the body 112) may be manipulated and varied by a designer of the wick structure to achieve a certain performance of the heat transfer apparatus and/or certain results.

As shown in FIG. 2, according to some embodiments of the present invention, for example, the body 112 of the wick structure 110 may have a gyroidal geometry. A gyroid is an infinitely connected triply periodic minimal surface, and the gyroid surface can be trigonometrically approximated by the equation:

$$sin x cos y + sin y cos z + sin z cos x = 0$$

According to embodiments of the present invention, the wick structure 110 may be configured to maximize a thermal performance of the heat transfer apparatus, as described in greater detail herein. For example, in some cases the wick structure 110 is configured to promote heat transfer in at least one predetermined area of the heat transfer apparatus 100 corresponding to a hot spot 103 of the heat source 102, as described in greater detail below.

A hot spot 103 may be an area or location in the heat source 102 having a higher concentration or intensity of heat. In some cases, the hot spot 103 may, for example, correspond to the location of a component or subcomponent of the heat source 102 that is generating the heat. As another example, the hot spot 103 may correspond to a structure, area, or location of the heat source where heat generated in other parts of the heat source 102 or its surroundings accumulate.

Because hot spots 103 are hotter than other parts of the heat source 102, it may be more important to remove heat from the hot spot more quickly and/or more efficiently than the heat is removed from other parts of the heat source in order to avoid the ill effects of elevated temperatures on the heat source or its surroundings. As such, according to embodiments of the present invention, the geometry of the wick structure 110 (gyroidal or otherwise) may be configured (e.g., sized and shaped) to target such hot spots 103 by preferentially removing heat from a certain location (or locations) of the heat transfer apparatus 100 that corresponds to (e.g., aligns with or matches up to) the location of the hot spot 103 on the heat source 102. The geometry may be configured, for example, to promote heat transfer in at least two predetermined areas of the heat transfer apparatus 100 corresponding to two hot spots 103 of the heat source 102, as shown in FIG. 1.

For example, in some cases, the wick structure 110, through the design of its geometry, may be configured to define at least one predetermined path between the evaporator section 120 and the condenser section 125 of the heat transfer apparatus 100. The predetermined path may be a route via which the working fluid from the condenser section 125 (e.g., following condensation of the evaporated working fluid) is encouraged to travel to reach the evaporator section 120. In some cases, the size of the pores 114 defined by the body 112 may be sized and/or shaped to facilitate or impede the flow of working fluid, such as by changing the capillary action (capillarity) in certain areas of the body. Additionally or alternatively, in some embodiments, the wick structure may be anisotropic, such that the flow of working fluid through the pores may occur in a desired direction (e.g., promoting capillary action in a first direction, but not in a second direction that is opposite the first direction), thereby reducing or eliminating backflow which would otherwise decrease the efficiency of the heat transfer apparatus. In other words, by designing the wick structure to be anisotropic, the distribution of working fluid within the chamber 106 may be optimized to encourage the flow of working fluid, upon condensation, from the condenser section 125 to the evaporator section 120 to pick up additional heat from the heat source for dissipation, thereby resulting in more efficient cooling of the heat source.

In this regard, capillary action may be defined as the spontaneous flow of a liquid into a narrow tube or porous material and occurs when adhesion forces between the liquid and the walls of the tube or material are stronger than the cohesive forces between the liquid molecules. In other words, capillary action is the result of the intermolecular forces between the liquid and the surrounding solid surfaces (e.g., between the working fluid and the surfaces of the body 112 of the wick structure 110). As such, capillary action requires that the pores 114 defined by the body 112 of the wick structure 110 be sufficiently small in diameter.

By varying the particular size of the pores 114, the capillary action through those pores can be increased or decreased (e.g., speeding up the flow of working fluid through certain pores or slowing down the flow of working fluid through certain other pores, respectively). Additionally or alternatively, the flow of working fluid through the body 112 may be manipulated by varying the dimensional parameters of the body 112 itself so as to change the surface area of the wick structure. Such variations may be made across the whole of the wick structure 110 or the identified locations (e.g., corresponding to the location of hot spots). For example, the diameter d of the interconnecting extensions 113 of the body that define the pores 114 (FIG. 2) may be increased or decreased. Additionally or alternatively, the absolute thickness t of the wick structure 110 between an inner surface of the housing 104 and an exterior surface of the wick structure 110 (FIG. 1) may be increased or decreased.

In some cases, the pores 114 defined by the body 112 of the wick structure 110 may have a variable pore size configured to optimize the capillary action of the pores. As will be understood by one skilled in the art in view of this disclosure, the capillary action of the pores 114 may be optimized by optimizing one or more of a direction of flow, a path of flow, or a speed of flow of the working fluid such as to achieve a predetermined design. In this way a greater amount of heat from the heat source 102 may be dissipated in a shorter amount of time as compared to convention heat pipes, vapor chambers, and other cooling fixtures or heat transfer apparatuses.

Additional parameters of the heat transfer apparatus may be optimized in some embodiments in order to provide an improved heat transfer apparatus according to embodiments of the present invention. For example, thermal conduction (e.g., the transmission of heat) through the wick structure may be optimized in some cases. In still other cases, a structural integrity of the heat transfer apparatus may be optimized. In this regard, as an example, decreasing the diameter d of the interconnecting extensions 113 of the body 112 of the wick structure 110, while potentially beneficial for decreasing an overall weight of the heat transfer device 100 and/or for increasing thermal conductivity and/or for configuring a predetermined path between the evaporator section 120 and the condenser section 125, may serve to decrease the structural integrity of the heat transfer apparatus because smaller-diameter (e.g., thinner) interconnecting extensions 113 may be inherently less capable of supporting the same maximum load that can be supported by larger-diameter (e.g., thicker) interconnecting extensions due to the presence of less material in the smaller-diameter areas.

Accordingly, in some embodiments, the dimensional parameters of the wick structure 110 (e.g., the diameter d of the interconnecting extensions 113 and/or the absolute thickness t of the wick structure 110) may be configured to optimize at least one of (i) the capillary action of the pores, (ii) thermal conduction through the wick structure, or (iii) a structural integrity of the heat transfer apparatus. In some embodiments, the pores 114 defined by the body 112 of the wick structure 110 have a variable pore size configured to optimize at least one of (i) the capillary action of the pores, (ii) thermal conduction through the wick structure, or (iii) a structural integrity of the heat transfer apparatus.

In some embodiments, the housing 104 may be made by additive manufacturing (e.g., three-dimensional printing), such as in cases in which the wick structure is formed in the same process or integrally with the housing. In other embodiments, the housing 104 may be formed by stamping, forging, machining, or another suitable manufacturing method. The material of the housing may be copper, aluminum titanium, steel, or any other suitable metal considering the parameters of the application in which the heat transfer apparatus will be used. Similarly, the wick structure 110 may be made by additive manufacturing (e.g., three-dimensional printing). Embodiments of the wick structure made by additive manufacturing may be used in vapor chambers having a larger thickness than wick structures made by chemical etching, as wick structures made by chemical etching are typically limited to very thin vapor chambers of less than 2 mm or so. The wick structure 110 may be made of copper, titanium, steel, or other materials suitable for the wick structure as understood by one skilled in the art in light of the present application. Moreover, in some embodiments, the wick structure 110 may be made separately from the housing 104 and then applied to or affixed to the interior of the housing, such as by using a diffusion bonding technique, while in other embodiments the wick structure 110 may be integrally formed with the housing 104, such as when the housing and the wick structure are both created using additive manufacturing.

Turning to FIG. 3, in some cases, the heat transfer apparatus 100 may further comprise at least one post 130 disposed within the chamber 106 and affixed to the housing 104. The at least one post 130 may be configured to increase a structural integrity of the heat transfer apparatus 100. For example, as shown in FIG. 3, posts 130 may be disposed in locations within the chamber 106 such that each post spans a distance between two opposite walls of the housing 104, thereby reinforcing the strength of the housing 104. In other words, by positioning posts 130 within the chamber 106, such as in areas where there is no lateral reinforcement (e.g., in locations between and spaced from the side walls 132) forces F applied to the upper and/or lower walls 134 of the housing 104 may be absorbed and supported by the posts 130, in addition to being supported by the side walls 132. The posts 130 may be made of copper, aluminum, titanium, or other suitable metal for providing structural support. Moreover, in some embodiments, the material of the post (e.g., copper) may be wrapped in the wick material to provide an additional wicking pathway from the condenser section 125 to the evaporator section 120 of the heat transfer apparatus 100 via capillary action, as described further below.

In some embodiments, the at least one post 130 may be hollow. For example, in cases where it is necessary to minimize the weight of the heat transfer apparatus 100 but additional structural integrity is needed, one or more posts 130 may be installed where the posts are hollow.

The at least one post 130 may be fixed to the housing 104 (e.g., to the upper and lower walls 134 of the housing) using sintering or diffusion bonding. In still other embodiments, however, the at least one post 130 may be formed integrally with the housing 104, as noted above. For example, in cases where the housing 104 is made via additive manufacturing, the post(s) 130 may also be made using additive manufacturing. Accordingly, in some embodiments, the at least one post 130 may be made of the same material as the housing 104. In other embodiments, the at least one post 130 may be made of a different material than the housing 104 and/or may have a different structure than the housing.

In some cases, the at least one post 130 may comprise a secondary wick structure that is configured to move the working fluid from the condenser section 125 to the evaporator section 120 of the heat transfer apparatus 100 via capillary action. For example, in some embodiments, the secondary wick structure may comprise a repeatable, configurable, and controlled geometry as described above, such as the gyroidal geometry shown in FIG. 2. In this regard, the at least one post 130 configured to have a secondary wick structure may be strategically disposed in the chamber 106 to create an additional path for moving working fluid from the condenser section 125 to the evaporator section 120 (e.g., in addition to the pathways created in the wick structure 110). For example, the post(s) 130 may comprise a structural core (e.g., a core made of copper, titanium, or other metal) surrounded by a wicking material (e.g., a material that incorporates a wick geometry as described above) to provide the secondary wick structure.

Accordingly, embodiments of the heat transfer apparatus 100 incorporating a wick structure 110 as described above may have marked advantages over conventional wick structures, such as copper mesh structures or copper powder structures. For example, as shown in the charts below, a wick structure made in accordance with embodiments of the present invention may have a fill time that is improved by 47.8% over a conventional copper mesh wick structure, where both wick structures have the same area and shape:

| Type of Wick Structure | Full Filling time (seconds) | Improved by: |
|---|---|---|
| Copper Mesh | 4.196 | 47.8% |
| Gyroidal | 2.189 | |

Although improvements of the fill time by 47.8% over a conventional copper mesh wick structure have been measured based on initial experiments in the example above, further improvements may be achieved.

Moreover, a wick structure made in accordance with embodiments of the present invention may have a fill time that is improved 53.8% over a conventional copper powder wick structure, where both wick structures have the same area and shape:

| Type of Wick Structure | Full Filling time (seconds) | Improved by: |
|---|---|---|
| Copper Powder | 5.167 | 53.8% |
| Gyroidal | 2.386 | |

Although improvements of the fill time by 53.8% over a conventional copper powder wick structure have been measured based on initial experiments in the example above, further improvements may be achieved.

In this regard, embodiments of the heat transfer apparatus 100 constructed to include a wick structure 110 having a repeatable, configurable, and controlled geometry as described above, such as a gyroidal geometry, will provide improvements over conventional apparatuses with conventional wick structures. The optimized design of the wick structure 110 according to the embodiments described above will reduce or eliminate randomness in the resulting wick structure, thereby allowing users to design the wick structure to have an anisotropic geometry that optimizes capillary action and optimizes the thermal performance of the heat transfer apparatus.

As will be understood by one skilled in the art in light of this disclosure, permeability is the ability of a capillary core to transport medium and can be represented by the value K. The greater the permeability K of a wick structure, the less impedance to flow there will be within the wick structure. According to some embodiments, the wick structure 110 of the heat transfer apparatus 100 may be designed to have a permeability value K of around 1.87 times the K value of a conventional wick structure (e.g., a wick structure made of copper mesh or copper powder). The higher the permeability K, the greater the capacity of the material to allow fluid to pass through it. Permeability K may be related to other characteristics of a conventional wick structure (e.g., copper powder), including powder size D, capillary porosity ε, and morphology coefficient X (which is dependent on the morphology of the particular material selected for the wick structure) through the following equation:

$$K = \frac{{D}^{2} {ε}^{2}}{{X ( 1 - ε )}^{2}}$$

With respect to the morphology coefficient X, the wick structure 110 according to embodiments of the present invention benefits from a value of X that is less than 150, such as, for example, in the range of 80-100, so as to result in a larger value of permeability K. The value of the coefficient X, however, is dependent on the morphology of the material, or the internal structural arrangement of the material.

The value of D in the equation above, when applied to the geometry of the wick structure 110 according to embodiments of the present invention described herein, is representative of the diameter of the pores 114. As such, the wick structure 110 may be designed to achieve a desired permeability value K based on the particular application (e.g., the location of hot spots, the amount of heat to be dissipated, etc.). To achieve the desired permeability K, an appropriate pore diameter D, a morphology coefficient X that is in the desired ideal range of 80-100, and a capillary porosity F may be selected (e.g., through the use of computer modeling software). In cases where the pores 114 are not spherical, an effective diameter or nominal diameter may be used for the value D. Moreover, in some embodiments, the equation noted above may be applied locally, such that different regions of the wick structure 110 are designed to achieve different permeability values K depending on proximity to the hot spot(s), as an example. As such, the wick structure 110 may be configured to have different pore diameters D in different locations and/or may have different morphology coefficients X and/or capillary porosities F. In this way, the wick structure 110 may be specifically designed to have the desired permeability K and achieve the desired amount of heat transfer on a localized scale, optimizing the overall performance of the wick structure according to the particular application.

Once the design (e.g., the particular geometry) of the wick structure has been determined, such as using computer modelling to achieve the desired, optimized performance according to the equation as described above, this determined geometry can be reproduced for making a number of heat transfer devices, such as by using additive manufacturing as described above. In other words, according to embodiments of the invention as described herein, a heat transfer device is provided that (1) is “repeatable” in that the particular geometry of the wick structure can be reproduced across numerous wick structures for numerous heat transfer devices requiring the same performance for which the geometry was optimized and designed; (2) is “configurable” in that the geometry of the wick structure is not required to be the same throughout the wick structure (e.g., it does not need to have a single repeated pattern), but rather can have different localized designs in different areas to achieve a desired overall performance (e.g., wick faster or slower or in one direction or another based on where the hot spot is); and (3) is “controlled” in that the geometry of the wick structure can be physically manufactured according to the calculated design, such as through the use of additive manufacturing.

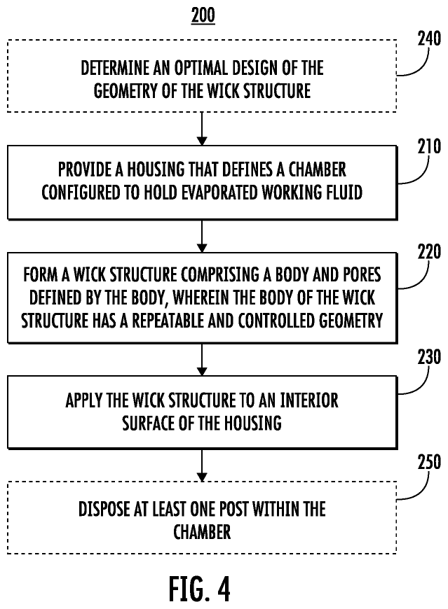

Turning now to FIG. 4, a flowchart of an example method for manufacturing a heat transfer apparatus is provided, where the heat transfer apparatus is configured to dissipate heat from a heat source, as described above in connection with the heat transfer apparatus 100 described above with reference to FIGS. 1-3. The method 200 may include providing a housing (such as the housing 104 described above in connection with FIGS. 1 and 3) that defines a chamber configured to hold working fluid at Block 210. A wick structure may be formed at Block 220, where the wick structure comprises a body and pores defined by the body. The body of the wick structure may have a repeatable, configurable, and controlled geometry, such as described above in connection with the wick structure 110 and shown in FIGS. 1-3. For example, the geometry of the wick structure 110 may be gyroidal. The wick structure may be applied to an interior surface of the housing at Block 230. For example, in some embodiments, forming the wick structure (Block 210) and applying the wick structure to an interior of the housing (Block 220) may comprise using an additive manufacturing process (e.g., three-dimensional printing). As such, the wick structure may, in some cases, be formed and applied to the interior of the housing concurrently, such as when an additive manufacturing process is used to build the wick structure directly on the interior surface of the housing. In other cases, however, the wick structure may be created (through additive manufacturing or other manufacturing methods) separately from the housing, then applied to the housing once formed (e.g., through the use of adhesive bonding techniques to bond the wick structure to the interior surface of the housing.

As described above, the heat transfer apparatus may define an evaporator section configured to evaporate the working fluid using heat from a heat source and a condenser section configured to dissipate heat carried by the evaporated working fluid through condensation of the evaporated working fluid. The pores of the wick structure may be configured to move the working fluid from the condenser section to the evaporator section via capillary action. Accordingly, the geometry of the wick structure may be configured to promote heat transfer in at least one predetermined area of the heat transfer apparatus corresponding to a hot spot of the heat source.

In some embodiments, as shown in Block 240, the method 200 may include determining an optimal design of the geometry of the wick structure. As described above in connection with FIGS. 1-3, the optimal design may optimize at least one of (i) the capillary action of the pores; (ii) thermal conduction through the wick structure; or (iii) a structural integrity of the heat transfer apparatus. In some cases, for example, the optimal design may include at least one of a variable diameter d of the interconnecting extensions of the body, a variable absolute thickness of the wick structure, or a variable size of the pores of the wick structure, as described above.

Additionally or alternatively, in some embodiments, the method 200 may further include disposing at least one post within the chamber (Block 250), where the at least one post is affixed to the housing. The at least one post may be configured to increase a structural integrity of the heat transfer apparatus, as described in greater detail above in connection with FIG. 3.

Many modifications and other embodiments of the present disclosure set forth herein will come to mind to one skilled in the art to which these embodiments pertain having the benefit of the teachings presented in the foregoing descriptions and the associated drawings. Although the figures only show certain components of the methods and apparatuses described herein, it is understood that various other components may also be part of any heat transfer apparatus or element thereof. In addition, the methods described above may include fewer steps in some cases, while in other cases may include additional steps. Modifications to the steps of the method described above, in some cases, may be performed in any order and in any combination. Moreover, in some embodiments, various steps may be performed simultaneously or substantially simultaneously.

Therefore, it is to be understood that the disclosure is not to be limited to the specific embodiments disclosed herein and that modifications and other embodiments are intended to be included within the scope of the appended claims. Although specific terms are employed herein, they are used in a generic and descriptive sense only and not for purposes of limitation.

That which is claimed:

1. A heat transfer apparatus configured to dissipate heat from a heat source, the apparatus comprising:
a housing defining a chamber configured to hold working fluid; and
a wick structure comprising a body and pores defined by the body, wherein the wick structure is disposed on an interior surface of the housing,
wherein the heat transfer apparatus defines an evaporator section configured to evaporate the working fluid using heat from a heat source and a condenser section configured to dissipate heat carried by the evaporated working fluid through condensation of the evaporated working fluid, and
wherein the wick structure comprises a repeatable, configurable, and controlled geometry that is configured to move the working fluid from the condenser section to the evaporator section via capillary action.

2. The heat transfer apparatus of claim 1, wherein the body of the wick structure has a gyroidal geometry.

3. The heat transfer apparatus of claim 1, wherein the geometry is configured to promote heat transfer in at least one predetermined area of the heat transfer apparatus corresponding to a hot spot of the heat source.

4. The heat transfer apparatus of claim 1, wherein the heat transfer apparatus is a cooling fixture comprising a vapor chamber or a heat pipe.

5. The heat transfer apparatus of claim 1, wherein the heat source is an integrated mircochip.

6. The heat transfer apparatus of claim 1, wherein the wick structure is anisotropic.

7. The heat transfer apparatus of claim 1, wherein dimensional parameters of the wick structure are configured to optimize at least one of (i) the capillary action of the pores, (ii) thermal conduction through the wick structure, or (iii) a structural integrity of the heat transfer apparatus.

8. The heat transfer apparatus of claim 1, wherein the pores defined by the body of the wick structure have a variable pore size configured to optimize at least one of (i) the capillary action of the pores, (ii) thermal conduction through the wick structure, or (iii) a structural integrity of the heat transfer apparatus.

9. The heat transfer apparatus of claim 1, wherein the geometry of the wick structure is configured to define at least one predetermined path between the evaporator section and the condenser section of the heat transfer apparatus.

10. The heat transfer apparatus of claim 1 further comprising at least one post disposed within the chamber and affixed to the housing, wherein the at least one post is configured to increase a structural integrity of the heat transfer apparatus.

11. The heat transfer apparatus of claim 10, wherein the at least one post is hollow.

12. The heat transfer apparatus of claim 10, wherein the at least one post comprises a secondary wick structure configured to move the working fluid from the condenser section to the evaporator section via capillary action.

13. The heat transfer apparatus of claim 1, wherein at least one of the housing or the wick structure is formed using an additive manufacturing process.

14. A method of manufacturing a heat transfer apparatus configured to dissipate heat from a heat source, the method comprising:
providing a housing that defines a chamber configured to hold working fluid;
forming a wick structure comprising a body and pores defined by the body, wherein the body of the wick structure has a repeatable, configurable, and controlled geometry; and
applying the wick structure to an interior surface of the housing,
wherein the heat transfer apparatus defines an evaporator section configured to evaporate the working fluid using heat from a heat source and a condenser section configured to dissipate heat carried by the evaporated working fluid through condensation of the evaporated working fluid, and
wherein the wick structure is configured to move the working fluid from the condenser section to the evaporator section via capillary action.

15. The method of claim 14, wherein forming the wick structure comprises using an additive manufacturing process.

16. The method of claim 14 further comprising determining an optimal design of the geometry of the wick structure, wherein the optimal design optimizes at least one of (i) the capillary action of the pores, (ii) thermal conduction through the wick structure, or (iii) a structural integrity of the heat transfer apparatus.

17. The method of claim 16, wherein the optimal design comprises at least one of a variable diameter d of interconnecting extensions of the body, a variable absolute thickness t of the wick structure, or a variable size of the pores of the wick structure.

18. The method of claim 14, wherein the geometry of the wick structure is configured to promote heat transfer in at least one predetermined area of the heat transfer apparatus corresponding to a hot spot of the heat source.

19. The method of claim 14, wherein the geometry of the wick structure is gyroidal.

20. The method of claim 14 further comprising disposing at least one post within the chamber, wherein the at least one post is affixed to the housing, and wherein the at least one post is configured to increase a structural integrity of the heat transfer apparatus.

21. A heat transfer apparatus configured to dissipate heat from a heat source, the apparatus comprising:
a housing defining a chamber configured to hold working fluid; and
a wick structure comprising a body and pores defined by the body, wherein the wick structure is disposed on an interior surface of the housing,
wherein the heat transfer apparatus defines an evaporator section configured to evaporate the working fluid using heat from a heat source and a condenser section configured to dissipate heat carried by the evaporated working fluid through condensation of the evaporated working fluid,
wherein the wick structure is configured to move the working fluid from the condenser section to the evaporator section via capillary action, and
wherein the body of the wick structure has a repeatable, configurable, and controlled geometry configured to maximize a thermal performance of the heat transfer apparatus.

22. The heat transfer apparatus of claim 21, wherein the geometry of the wick structure is gyroidal.

23. The heat transfer apparatus of claim 21, wherein the wick structure is formed using an additive manufacturing process.

24. The heat transfer apparatus of claim 21, wherein the wick structure comprises at least one of a variable diameter d of interconnecting extensions of the body, a variable absolute thickness t of the wick structure, or a variable size of the pores of the wick structure.
